(19) United States
(12) Patent Application Publication
(10) Pub. No.: US 2010/0186820 A1
(43) Pub. Date: Jul. 29, 2010

(54) Solar electricity generation with improved efficiency

(76) Inventor: Steven G. Schon, Strafford, PA (US)

Correspondence Address: KRISTOFER E. ELBING, 187 PELHAM ISLAND ROAD, WAYLAND, MA, 01778, US

(21) Appl. No.: 12/459,391

(22) Filed: Jun. 30, 2009

Related U.S. Application Data
(63) Continuation-in-part of application No. 12/291,544, filed on Nov. 10, 2008.
Application No. 12/291,544 is a continuation-in-part of application No. PCT/US2008/014081, filed on Dec. 26, 2008.

(51) Int. Cl. H01L 31/00; F24J 2/04; F24J 2/24; F03G 6/06

(52) U.S. Cl. 136/259; 126/643; 126/651; 60/641.15

(57) ABSTRACT

Solar electricity generation methods and apparatus are disclosed. In one general aspect, a solar cell is positioned to receive concentrated solar radiation and convert part of it into electricity and part of it into heat. A first heat exchanger is thermally coupled to the solar cell and includes microchannels that have a cross-sectional dimension to the center of the channel that is about equal to or less than the thermal boundary layer thickness for a working fluid. The heat exchanger transfers heat from the photovoltaic solar cell to the working fluid in the microchannels, and a second heat exchanger can then receive the transferred heat via a conduit. This heat can be used to generate additional electricity.

### CROSS REFERENCE TO RELATED APPLICATIONS

This application claims the benefit under 35 U.S.C. 119(e) of U.S. provisional application Ser. No. 61/017,198 filed Dec. 28, 2007, is a continuation-in-part of U.S. Ser. No. 12/291,544 filed Nov. 10, 2008, and is a continuation-in-part of PCT application number PCT/US2008/14081, filed Dec. 26, 2008. All of these applications are herein incorporated by reference.

### FIELD OF THE INVENTION

This application relates to solar energy generation, including methods and apparatus for improving the cooling efficiency of solar cells.

### BACKGROUND OF THE INVENTION

It is desirable to concentrate the light illuminating photovoltaic cells, as the cost per unit area of concentration devices (lenses, reflectors, etc.) is usually lower than the cost per unit area of active photovoltaic material. However, increasing the concentration of the illumination also tends to increase the heat load on the photovoltaic cell. It is also well-known that the electrical conversion efficiency of photovoltaic cells tends to decrease as the operating temperature of the cell increases. Because of this effect, photovoltaic cells tend to exhibit a maximum concentration factor, and above this maximum the total electrical output of the cell decreases, due to the progressively lower efficiencies accompanying the rising operating temperatures.

### SUMMARY OF THE INVENTION

Heat pipes are used for cooling and transferring heat away from hot objects to a physically separated cooler area or cooling device. Heat pipes may take the form of a single closed tube, or of a pair of tubes or pipes connected in a closed circuit. The full heat pipe system also includes a volatile “working fluid” enclosed in the heat pipe, the evaporation and condensation of which mediates heat transfer from one end of the heat pipe to the other. One end of the tube or closed piping circuit is provided with a means for collecting and absorbing heat (heat absorber) at an elevated temperature, causing the fluid to evaporate. The other end of the tube or piping circuit is provided with a means for rejecting heat (heat sink) at a lower temperature than the hot end. At the heat absorber, the volatile fluid evaporates and absorbs heat; the vapor expands in volume and travels to the heat sink, where it condenses and gives up its heat. The condensed fluid returns to the hot end by gravity or capillary action via a wick, repeating the cycle. The pressure inside the heat pipe rises to that corresponding to the vapor pressure of the working fluid at the fluid boiling temperature inside the heat absorber block.

In a single tube heat pipe, the vapor travels up the core of the tube, and the liquid returns counter-currently along the walls. In a two-pipe configuration, sometimes referred to a thermosyphon, the vapor travels up one pipe, and the liquid returns via the second pipe, which is usually smaller in diameter. Heat pipes have the advantage of very high heat transfer rates, and do not rely on any mechanically moving parts.

An essential consideration in designing heat pipes is the selection of the heat exchangers for the heat absorber and the heat sink. Their characteristics determine the rate at which heat can be transferred away from hot objects or fluids. The rate of heat transfer into the heat absorber, and/or the rate of heat transfer from the heat sink to the cooling medium, is often the limiting factor in the performance of heat pipes, especially if the ratio of the fluid internal surface area to the working fluid volume is relatively small in the absorber or the heat sink

Primary considerations in selecting a heat absorber or heat sink configuration are the mechanical design of the heat transfer surfaces (e.g., configuration, material layout and thickness, orientation, etc.), the modes of heat transfer (e.g., conduction and/or convection and/or radiation), and the physical properties (especially the thermal conductivity) of the materials of construction of the heat transfer materials in direct with the working fluid.

Heat pipes have hitherto typically used simple, conventional heat exchange designs for the heat absorber and the heat sink. These include hollow blocks or plates (with a cavity for the working fluid), shell-and-tube exchangers, plate heat exchangers, bare tubes or pipes, and tubes, pipes, or hollow blocks with extended surfaces. However, despite the variety of available configurations, there has still been a need for heat pipes with higher heat transfer rates than those traditionally available.

In one general aspect, the invention features a solar electricity generation system, that includes a solar concentrator positioned to receive and concentrate solar radiation, and a photovoltaic solar cell positioned to receive the concentrated solar radiation from the solar concentrator and operative to convert part of the energy in the concentrated solar radiation into electricity and part of the energy in the concentrated solar radiation into heat. A first heat exchanger includes a plurality of microchannels having a cross-sectional dimension to the center of the channel that is about equal to or less than the thermal boundary layer thickness for a working fluid. This heat exchanger is thermally coupled to the solar cell and is operative to transfer the heat from the photovoltaic solar cell to the working fluid in the microchannels. A conduit has a first end hydraulically responsive to the heat exchanger, and a second heat exchanger is hydraulically responsive to a second end of the conduit.

In preferred embodiments, the solar electricity generation system can further include an electric generator thermally coupled to the second heat exchanger and operative to produce electricity from heat transferred from the first heat exchanger to the second heat exchanger by the working fluid. The second heat exchanger can also comprise microchannels having a cross-sectional dimension to the center of the channel that is about equal to or less than the thermal boundary layer thickness for the working fluid. The heat exchangers and the conduit can be constructed and adapted to operate with a working fluid that changes phases during operation of the system. The solar electricity generation system can further include further photovoltaic solar cells responsive to concentrated solar radiation, further include further first heat exchangers thermally coupled to the further photovoltaic cells, and further include further conduits hydraulically connected between the further first heat exchangers and the second heat exchanger. The solar electricity generation system can further include a return conduit hydraulically connected between the first heat exchanger and the second heat exchanger to provide return fluid from the second heat exchanger to the first heat exchanger. The working fluid can be conveyed substantially only passively. The photovoltaic cell can have a shorter dimension and a longer dimension in a plane perpendicular to an illumination angle, with the microchannels of the heat exchanger being oriented perpendicular to the longer dimension. The microchannels can have a cross-sectional dimension of less than 1000 microns. The second heat exchanger can also comprise microchannels having a cross-sectional dimension of less than 1000 microns. The solar electricity generation system can further include a secondary loop containing a secondary working fluid responsive to heat from the working fluid used in the first heat exchanger, and one or more turbo-generators operative to receive vaporized secondary working fluid from the secondary loop.

In another general aspect, the invention features a solar electricity generation method that includes concentrating solar radiation and converting part of the energy in the concentrated solar radiation into electricity and part of the energy in the concentrated solar radiation into heat. At least some of the heat is transferred from the photovoltaic solar cell to a working fluid in a plurality of microchannels having a cross-sectional dimension to the center of the channel that is about equal to or less than the thermal boundary layer thickness for the working fluid, the working fluid is caused to flow to another location, and at least some of the heat is extracted from the working fluid after causing it to flow to another location. In preferred embodiments, the solar electricity generation system can further include the step of converting the extracted heat into further electricity.

In a further general aspect, the invention features a method of cooling a photovoltaic device or solar collector that includes providing a microchannel heat absorber comprising at least one layer defining a plurality of microchannels having a cross-sectional dimension of less than 1000 microns and terminating at a first end thereof in a cool side manifold and at a second end thereof in a warm side manifold, the microchannels containing a liquid working fluid that absorbs heat and forms a vapor upon flowing therethrough from the first end to the second end, a heat sink for receiving and condensing the vapor to reform the liquid working fluid and for discharging the liquid working fluid, and one or more pipes flowably connecting the warm side manifold of the heat absorber to the heat sink and flowably connecting the cool side manifold of the heat absorber to the heat sink, wherein the one or more pipes are connected so as to permit simultaneous flow of the vapor from the heat absorber to the heat sink and of the liquid working fluid from the heat sink to the heat absorber when heat is applied to the heat absorber. The method also includes the steps of installing the microchannel heat absorber in direct contact with the non-illuminated portion of the photovoltaic device and installing the heat sink at a distance sufficiently removed from the photovoltaic device to allow the heat sink to be rejected to ambient air.

In preferred embodiments, the microchannel heat absorber can be a parallel flow microchannel heat absorber. The microchannel heat absorber can be a cross-flow microchannel heat absorber. The thermal conductivity of the layer that defines the channels can be greater than 170 watts/m-° C. and the microchannels have a largest cross-sectional dimension of less than 250 microns. The method can be entirely passive. The photovoltaic device or solar collector can be of a design where the light intensity is amplified by concentrating means. The heat sink can be provided with a means for converting the waste heat to additional electricity. The means for converting the waste heat to additional electricity can comprise one or more thermo-electric generators. The thermo-electric generators can include one or more Seebeck-effect type devices. The means for converting the waste heat to additional electricity can comprise a secondary loop for a secondary working fluid, with the working fluid being vaporized and pressurized by the waste heat from the primary heat absorber system, with the pressurized secondary working fluid vapor being passed through a turbo-generators, and with the secondary working fluid vapor exiting the turbo-generator being condensed by the heat sink. The secondary working fluid can be the same as the working fluid used in the microchannel heat absorber.

In another general aspect, the invention features a solar electricity generation system that includes means for concentrating solar radiation, means for converting part of the energy in the concentrated solar radiation into electricity and part of the energy in the concentrated solar radiation into heat, means for transferring at least some of the heat from the photovoltaic solar cell to a working fluid in a plurality of microchannels having a cross-sectional dimension to the center of the channel that is about equal to or less than the thermal boundary layer thickness for the working fluid, means for causing the working fluid to flow to another location, and means for extracting at least some of the heat from the working fluid after causing it to flow to another location. In preferred embodiments, the solar electricity generation system further includes means for converting the extracted heat into further electricity.

### BRIEF DESCRIPTION OF THE DRAWINGS

FIG. 1 shows a prior art microchannel heat exchanger core suitable for use in making a heat pipe according to the invention.

FIGS. 2a and 2b show another prior art microchannel heat exchanger core suitable for use in making a heat pipe according to the invention.

FIG. 3 shows a heat pipe according to the invention, employing a heat absorber using a parallel flow microchannel core and two pipes for connection to the heat sink.

FIG. 4 shows a heat pipe according to the invention, employing a heat absorber using a parallel flow microchannel core and a single pipe for connection to the heat sink.

FIG. 5 shows a heat pipe according to the invention, employing a heat absorber using a cross-flow microchannel core and two pipes for connection to the heat sink.

FIG. 6 shows a heat pipe according to the invention, employing a heat absorber using a cross-flow microchannel core and a single pipe for connection to the heat sink.

FIG. 7 shows a heat pipe according to the invention, employing a heat sink using a parallel flow microchannel core and two pipes for connection to the heat absorber.

FIG. 8 shows a heat pipe according to the invention, employing a heat sink using a parallel flow microchannel core and a single pipe for connection to the heat absorber.

FIG. 9 is a graph showing the heat removal performance of two heat pipes according to the invention compared with prior art cooling devices.

FIG. 10 is a cross-sectional diagram of an illustrative embodiment of a solar electricity generation system employing microchannel heat exchangers,

FIG. 11 is a cross-sectional diagram of another illustrative embodiment of a solar electricity generation system,

FIG. 12 is a perspective diagram of the solar electricity generation system of FIG. 11;

FIG. 13 is a cross-sectional diagram of a collector for a further illustrative embodiment of a solar electricity generation system;

FIG. 14 is a perspective diagram of the solar electricity generation system of FIG. 13 with its input manifold removed to show flow direction; and

FIG. 15 is a plot of an assumed relationship between efficiency and cell temperature;

FIG. 16 is a calculated plot of cell temperature against concentration factor and cooling mode; and

FIG. 17 is a calculated plot of delivered power against concentration factor and cooling mode.

### DETAILED DESCRIPTION OF ILLUSTRATIVE EMBODIMENTS

According to the invention, so-called “microchannel” heat exchange devices, sometimes also known as “printed circuit” heat exchangers, are used as the heat absorber and/or the heat sink for heat pipes. The inventors have found that heat pipes incorporating such devices afford exceptionally high heat transfer rates between the heat source or sink and working fluid. Without wishing to be bound by any particular theory or explanation, the inventors speculate that the very high efficiency of the inventive heat pipes may result from overcoming a limitation of typical conventional heat pipes, namely that the heat transfer capacity of the central tubular section of the pipe is significantly higher than is realized, due to limitations in the rates at which the heat absorber and/or heat sink transfer heat to and from the central section. In typical conventional configurations, the conductive material in contact with the working fluid and the heat source or cooling medium is relatively thick, typically on the order of 1.2-15 mm in the thinnest dimension. This may limit the rate of heat transfer, due to thermal resistance of the heat exchange material. It is also speculated that heat transfer is further impeded by the fluid film resistance at the boundary layer of the boiling or condensing working fluid adjacent to the heat exchanger material.

The fluid velocity (hydrodynamic) boundary layer thickness is a function of the Reynolds number (Re), and the thermal boundary layer thickness is a function of the hydrodynamic boundary layer thickness divided by the cube-root of the Prandtl number (Pr). The particular functions and equations depend on the system geometry (e.g. flat plates vs. tubes); although phase change can complicate matters.

Re=velocity*characteristic length*density/viscosity

Pr=heat capacity*viscosity/thermal conductivity

The characteristic length is the diameter for tubes, and the hydraulic diameter for non-circular channels.

The ratio of the convective to conductive heat transfer across (normal to) the boundary is given by the Nusselt number (Nu).

Nu=heat transfer coefficient*thermal conductivity/characteristic length

In laminar flow (as is the case in microchannels), the Nusselt number is a constant (at least for a given phase), so it can be seen that the heat transfer improves with the inverse of the diameter of channel thickness. This is why heat transfer improves dramatically as the channels get smaller. (The trade-off is the increasing pressure drop/flow reduction as the channels get smaller).

For internal flows (e.g. closed channels and tubes), the flow is laminar when Re<2200. So, one skilled in the art of fluid mechanics can calculate the hydrodynamic and thermal boundary layer thicknesses for known fluid properties, flow conditions, and channel geometry. The maximum microchannel diameter/thickness should be twice the lesser of the either the thermal boundary layer or hydrodynamic boundary layer thickness (factor of two because the boundary layer can extend no farther than the mid-point of the channel).

From the fluid boundary layer equation pertinent to the geometry of interest, which is a function of Re, and the velocity, density, and viscosity (used to calculate Re), one can solve for the limiting dimension or thickness such that the fluid boundary layer thickness is equal to the distance from the wall to the centerline, when Re=2200.

From the thermal boundary layer equation pertinent to the geometry of interest, which is a function of fluid boundary layer thickness divided by the cube-root of Pr, and the heat capacity, thermal conductivity and viscosity (used to calculate Pr), one can calculate the thermal boundary layer thickness.

In contrast to conventional heat pipes, the heat absorber and/or heat sink sections of the inventive heat pipes have sub-millimeter channels and wall thicknesses whose characteristic length is smaller than the thermal boundary layer thickness, substantially reducing both the conductive resistance and the convective/thermal resistance values. While microchannel heat exchangers have been used in ordinary heat transfer services, they have not hitherto been used in conjunction with heat pipes, to transfer heat at high rates between physically separated heating and cooling sources.

The heat pipes of the present invention provide significant enhancement of heat transfer by maximizing heat exchange at the heat absorber and/or heat sink though the use of microchannel heat exchange devices, coupled with the high heat transfer rates over distances associated with the phase changes and movements of the working fluid. In some embodiments of the invention, the heat absorber and/or the heat sink are passive, by which it is meant that no pumps, fans, valves, or other energy-consuming devices are employed in their operation. An entirely passive heat pipe results if both the heat absorber and the heat sink are passive.

The heat pipes of the present invention may also be particularly advantageous for use in photovoltaic electric power generating systems, such as those that employ photocells, solar collectors, and the like, to convert light to electricity. Existing photovoltaic cells generally only use a portion of the light spectrum for photovoltaic conversion; with the unusable portion of the spectrum impinging on the photovoltaic devices being converted to heat, which tends to raise the temperature of the devices and can increase the electrical resistance of the components. This reduction in conversion efficiency with increasing temperature of photovoltaic devices is well known, and it can present a particularly acute problem for solar-concentrator systems, in which the light intensity impinging on the photovoltaic device is amplified up to several orders of magnitude using a system of mirrors and/or lenses spread out across a larger light-gathering area. Solar concentrator systems are therefore often equipped with air- or water-cooled blocks backing the photovoltaic cells, to minimize the temperature rise of the photovoltaic cells. In these systems, however, the heat removal can be limited by the heat flux that attainable by the cooling blocks, which can in turn be limited by the thermal conductivity of relatively massive blocks. Furthermore, the cooling block systems often require complex and massive auxiliary equipment, such as pumps or fans and radiators, which can constrain the design flexibility and increase the costs of the solar concentrator installations. The application of heat pipes according to the invention can help to solve these problems and more efficiently, preferably passively, remove the heat from photovoltaic cells, especially those used in solar concentrator systems. This can allow for higher electrical conversion efficiency, and increase the design flexibility of solar installations.

The invention will next be illustrated with reference to the Figures, wherein similar numbers indicate similar elements in all Figures. The Figures are intended to be illustrative rather than limiting and are included to facilitate explanation of the invention. The Figures are not to scale, and are not intended to be engineering drawings. Also, it will be appreciated that the devices of the invention may be used for a wide variety of applications, and accordingly the dimensions and materials useful for making them also cover a wide range, and are sometimes interdependent. Therefore, the invention should not be construed as limited by the materials and dimensions explicitly noted in the Figures and associated text.

### Heat Pipes Employing Microchannel Heat Absorbers

Prior art microchannel heat exchangers are used as the heat absorber and optionally as the heat sink for heat pipes according to the invention. The cores of the microchannel heat exchangers comprise one or more layers of parallel microchannels, wherein the largest cross-sectional dimension of the microchannels is less than 1000 microns, and preferably less than 250 microns, and the materials of construction of the heat transfer surfaces are materials with thermal conductivities in excess of 5 watts/m-° C., and preferably in excess of 17 watts/m-° C., and most preferably in excess of 170 watts/m-° C. If more than one layer of microchannels is used, the number of layers may be any number from 2 to 10, or in some cases an even larger number, e.g., as high as 20.

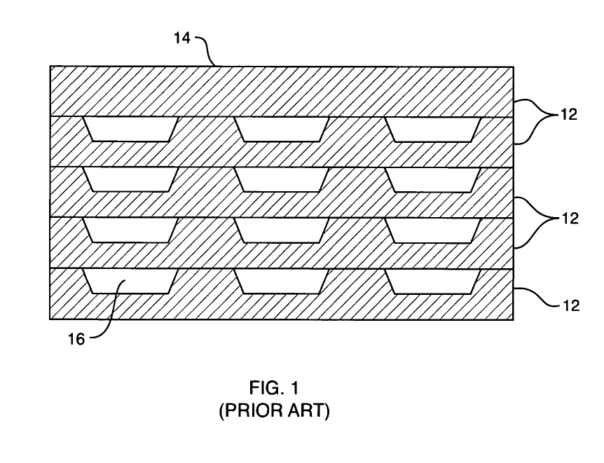

Referring now to FIG. 1, the working fluid microchannels 16 of a parallel flow microchannel core 14 for a heat exchanger may optionally be arranged in multiple layers 12, whereby heat transfer to outer layers is achieved by thermal conduction through the material walls connecting the layers of the microchannels. This increases the total effective heat transfer area (internal to the microchannel device) available for evaporation or condensation of the working fluid, without requiring an increase in the surface area in contact with the heat source or sink. When multiple layers are used, each layer is typically fabricated from a thin sheet with etched open channels or grooves, and the layers are bonded or fused to each other, sealing the open tops of the channels or grooves, forming closed microchannels. This arrangement results in a monolithic heat exchanger, with only one thin conducting surface interspersed between adjacent stacks of fluid channels. It also eliminates the need for a conductive spacer and its associated resistance to heat transfer. Such devices are available commercially, with one example being “Ardex” liquid coolers, manufactured by Atotech Deutschland GmbH, headquartered in Berlin, Germany. By using such a configuration for the heat absorber, the heat pipes of the present invention enjoy inherently high rates of conductive heat transfer.

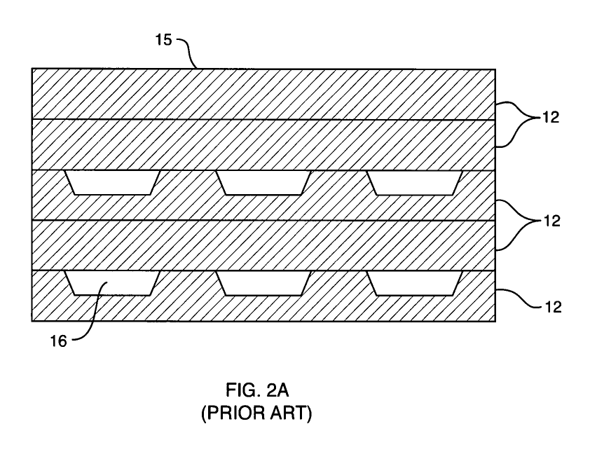

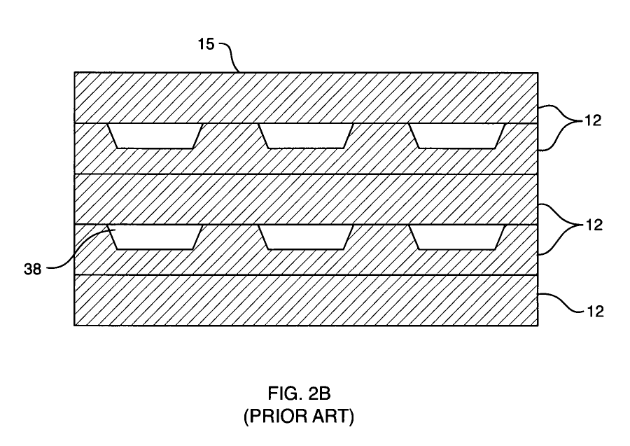

FIGS. 2a and 2b depict another prior art heat exchanger core, shown generally at 15, suitable for use in heat pipes according to the invention. Core 15, referred to herein as a cross-flow microchannel core, has two or more alternating layers 12 of microchannels, i.e., working fluid microchannels 16 as described above alternating with intermediate fluid microchannels 38. The orientation of the layers is such that alternating layers meet at common inlet and outlet regions, allowing the intermediate fluid to flow through the unit without co-mingling with the working fluid. The intermediate fluid may be any liquid or gas suitable for transferring heat away from cross-flow microchannel core 15 (in the case where the core is used in a heat sink) or to core 15 (if the core is used in a heat absorber). It is preferable to arrange the channel and layer orientation so that two fluids flow through their respective channels in directions substantially perpendicular to each other. FIG. 2a shows the heat exchanger from the side showing the working fluid microchannels 16, and FIG. 2b shows it from a side perpendicular to the first, i.e., rotated 90° about a vertical axis, showing the intermediate fluid microchannels 38. Such devices are available commercially, with one example being a Printed Circuit Heat Exchanger (PCHE), manufactured by Heatric, headquartered in Dorset, England.

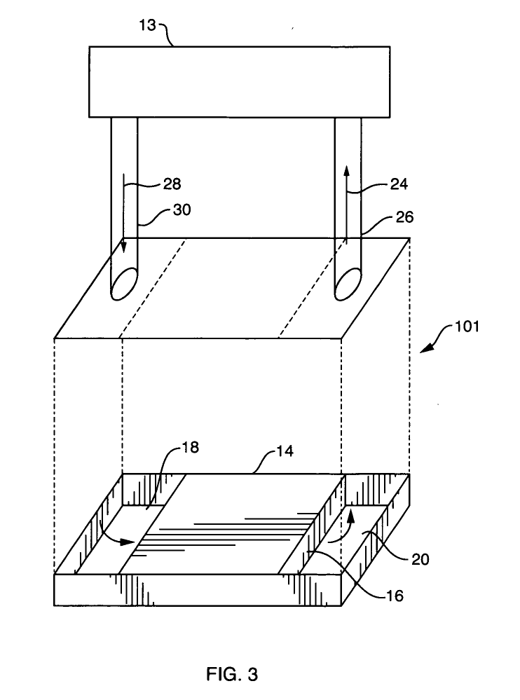

Referring now to FIG. 3, there is shown an exploded view of a microchannel heat absorber 101 for use in a heat pipe according to the invention. This type of heat pipe is a 2-pipe configuration, also known as a thermosyphon. Heat is conducted from the heat source, i.e., the object or fluid that is to be cooled (not shown), through the surface of the bottom-most layer of core 14 by conduction. The heat is further conducted into the working fluid microchannels 16 of the parallel flow microchannel core 14, constructed for example as shown in FIG. 1. Where multiple layers of microchannels are used in core 14, some of the heat is conducted to the succeeding layers by conduction through the sidewalls of layers.

The heat absorber is connected to an elevated heat sink shown schematically at 13 by means of two pipes or tubes of ordinary dimensions, typically having an inside diameter from about 50 mils to about one inch. However, there is no fundamental limit to the diameter—the larger the diameter, the higher the axial power rating, i.e. the amount of heat that can be transferred between the heat source and the heat sink. Thus, the diameter may be 2 or 3 inches or even greater. Vaporized working fluid exits parallel flow microchannel core 14 into the warm side manifold 20 and flows from the heat absorber to the heat sink by means of warm side pipe 26 (preferably of larger diameter than cool side pipe 30). At heat sink 13, the working fluid gives up its heat to a cooling medium, causing it to condense back to liquid. The condensed liquid working fluid returns from the heat sink by gravity via cool side pipe 30 to cool side manifold 18 and then into parallel flow microchannel core 14, completing the cycle.

While heat sink 13 is preferably a microchannel heat exchanger, it may alternatively be of any of any convenient design to facilitate condensation of the working fluid, e.g., a conventional heat exchanger, air-cooled finned tubes or hollow plates, thermoelectric cooler, etc.

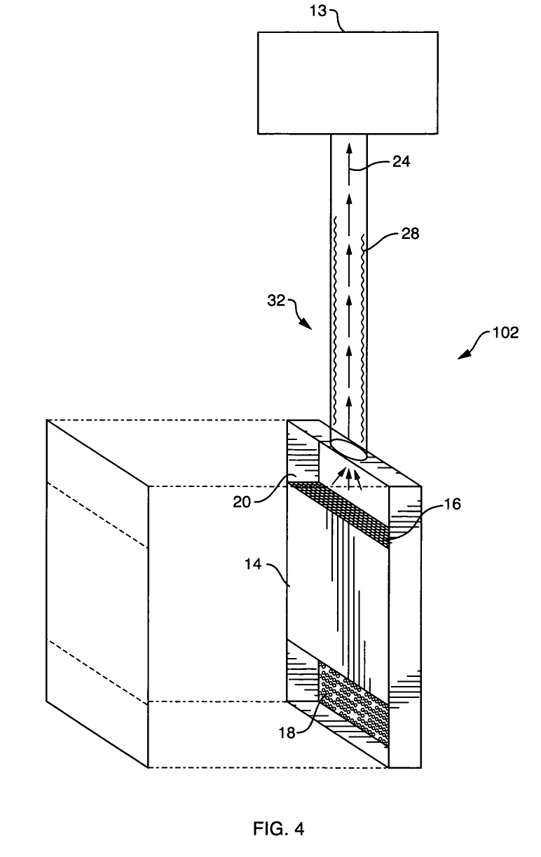

FIG. 4 shows an embodiment of the invention in which the heat absorber 102 is similar to that described in FIG. 3, but is connected to heat sink 13 by means of common connecting pipe 32, through which vaporized working fluid 24 and liquid working fluid 28 move co-axially and counter-currently. The heat pipe functions in a manner similar to that of FIG. 3, except that vaporized working fluid 24 moves through the central portion of common connecting pipe 32, and liquid working fluid 28 travels along the walls of the pipe, e.g., as a moving annular film. In another embodiment (not shown), common connecting pipe 32 has an annular or co-axial wick for co-axial counter-flow of the liquid and vaporized working fluid. For example, the walls of the connecting pipe may be lined with an annular band of, or packed co-axially with, a porous wicking material. The liquid travels by capillary action through the porous wicking material. This allows the heat pipe to be oriented other than substantially vertically, e.g., with the heat sink level with or even below the heat absorber.

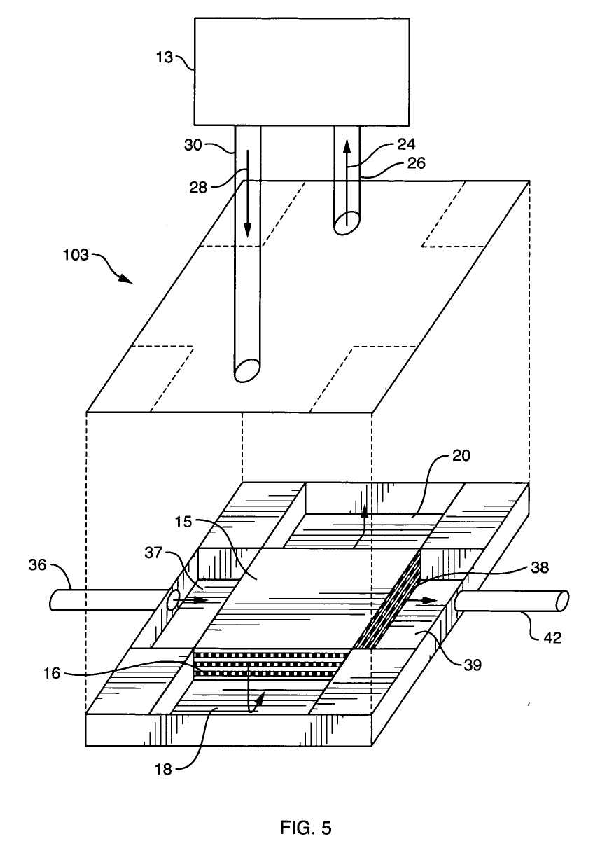

FIG. 5 shows another embodiment of the invention, employing a heat absorber 103 that includes a cross-flow microchannel core 15 such as shown in FIG. 2. Heat is transferred from the heat source to heat absorber 104 by means of an intermediate fluid, e.g., liquid, gas, or condensable vapor. The relatively hot/warm intermediate fluid enters through inlet pipe 36 into inlet manifold 37, flows through intermediate fluid microchannels 38, exits cross-flow microchannel core 15 into outlet manifold 39 at a lower temperature, and exits the heat absorber via outlet pipe 42. While in cross-flow microchannel core 15, the intermediate fluid is cooled by the working fluid through heat conduction into the (boiling) working fluid in the intervening layers, via the walls of the working fluid microchannels 16 and the intermediate fluid microchannels 38.

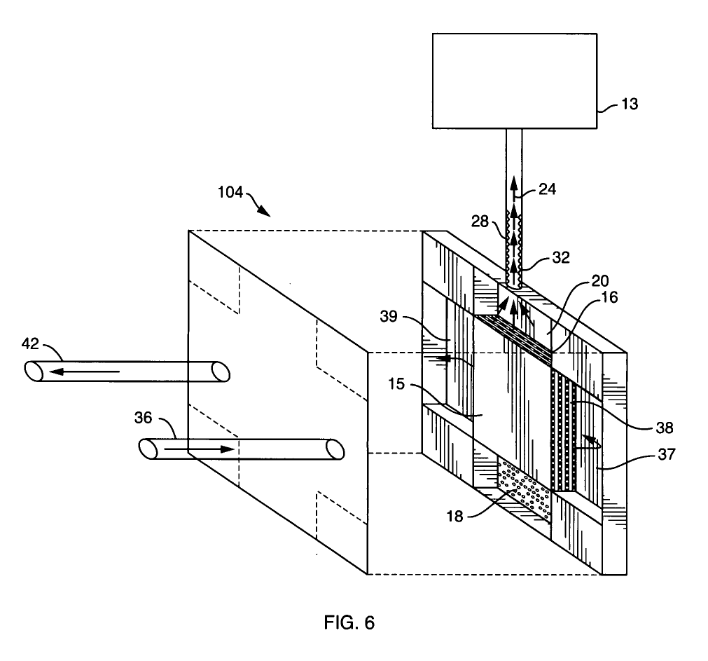

FIG. 6 shows another embodiment of the invention, in which the heat absorber 104 is connected to a heat sink shown schematically at 13 by means of common connecting pipe 32, through which vaporized working fluid 24 and liquid working fluid 28 move co-axially and counter-currently. The vapor moves through the central portion of the connecting pipe, and the liquid travels along the walls of the pipe, e.g., as a moving annular film. Heat is transferred from the heat source to heat absorber 103 by means of an intermediate fluid, e.g., liquid, gas, or condensable vapor. The intermediate fluid enters through inlet pipe 36 into inlet manifold 37, flows through intermediate fluid microchannels 38, exits cross-flow microchannel core 15 into outlet manifold 39, and exits 103 via outlet pipe 42. While in cross-flow microchannel core 15, the intermediate fluid is cooled by the (boiling) working fluid through heat conduction into the working fluid in the intervening layers, via the walls of the working fluid microchannels 16 and the intermediate fluid microchannels 38. In another embodiment (not shown), common connecting pipe 32 has an annular or co-axial wick for co-axial counter-flow of the liquid and vaporized working fluid. For example, the walls of the connecting pipe may be lined with an annular band of, or packed co-axially with, a porous wicking material. The liquid travels by capillary action through the porous wicking material. This allows the heat pipe to be oriented other than substantially vertically, e.g., with the heat sink level with or even below the heat absorber.

### Heat Pipes Employing Microchannel Heat Sinks

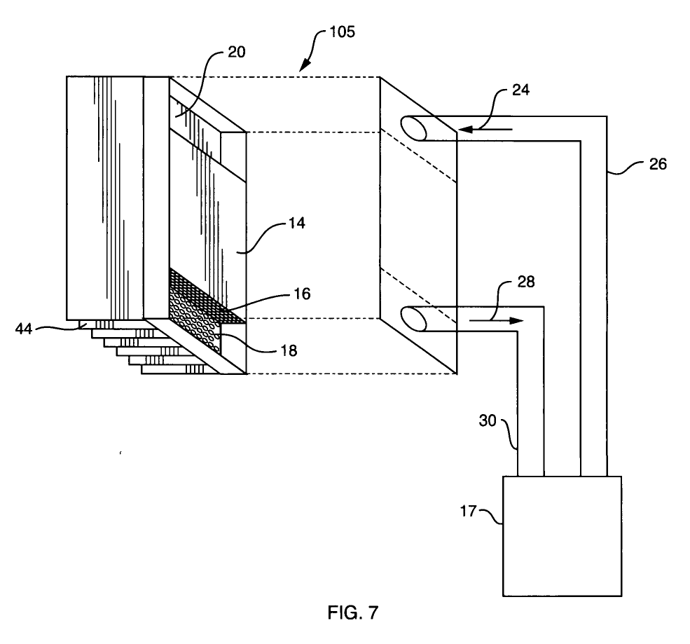

Referring now to FIG. 7, there is shown an embodiment of the invention in which the heat sink 105 is a microchannel heat exchanger with extended surfaces cooled by natural or forced convection with air or other fluid coolants, and the heat pipe has separate connecting pipes for the liquid and vaporized working fluid. The structure is similar to that of the heat absorber shown in FIG. 3, with the addition of cooling surfaces 44, and the spatial orientation is typically as shown in FIG. 7, i.e., rotated about a horizontal axis extending into the page 90° relative to the way it would be oriented when used as a heat absorber such as in FIG. 3.

The cooling surfaces 44 are provided on the outside of one or both sides of a single-layer unit, or the outsides of one or both of the outermost layers in a multi-layer unit. They may comprise thin extensions of thermally conductive material, to provide additional heat transfer surface area exposed to the air or other final cooling medium. The extended surfaces may be of any convenient geometry or orientation, e.g., pins, parallel perpendicular fins, spaced fibers, ribs, and the like.

Heat sink 105 is connected to a microchannel heat absorber shown schematically at 17 located at a lower elevation by means of two pipes or tubes of ordinary dimensions, typically having an inside diameter from about 50 mils to about one inch. However, there is no fundamental limit to the diameter—the larger the diameter, the higher the axial power rating. Vaporized working fluid flows from the heat absorber to the heat sink by means of warm side pipe 26 and enters parallel flow microchannel core 14 at warm side manifold 20. Heat is conducted out of the heat sink via cooling surfaces 44 into a surrounding fluid, which may be a gas such as air or a liquid, resulting in condensation of the working fluid in working fluid microchannels 16. The condensed liquid working fluid exits parallel flow microchannel core 14 at cool side manifold 18 returns via cool side pipe 30 to by gravity to the heat absorber. Warm side pipe 26 is preferably connected at a high point above parallel flow microchannel core 14.

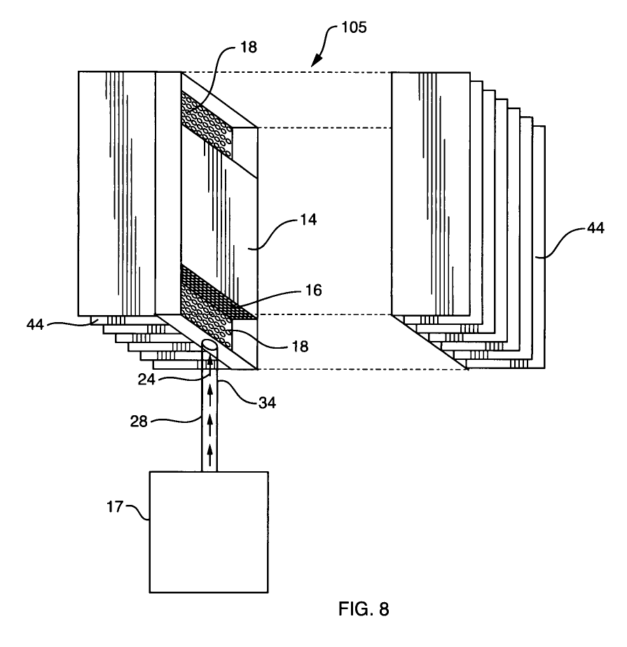

FIG. 8 shows an embodiment of the invention in which the heat sink, shown generally at 106, is a microchannel heat exchanger similar to the heat absorber shown in FIG. 4, with the addition of cooling surfaces 44 as described above. As shown in FIG. 8, its typical orientation will be inverted relative to the orientation when used as a heat absorber.

Vaporized working fluid 24 flows from the heat absorber shown schematically at 17 to the heat sink by means of common connecting pipe 32 and enters parallel flow microchannel core 14 at warm side manifold 20. Heat is conducted out of the heat sink via cooling surfaces 44 into a surrounding fluid, which may be a gas such as air or a liquid, resulting in condensation of the working fluid in working fluid microchannels 16. Condensed liquid working fluid 28 travels along the walls of common connecting pipe 32, e.g., as a moving annular film. In another embodiment (not shown), common connecting pipe 32 has an annular or co-axial wick for co-axial counter-flow of the liquid and vaporized working fluid. For example, the walls of the connecting pipe may be lined with an annular band of, or packed co-axially with, a porous wicking material. The liquid travels by capillary action through the porous wicking material. This allows the heat pipe to be oriented other than substantially vertically, e.g., with the heat sink level with or even below the heat absorber.

In another embodiment of the invention, the heat sink is constructed in substantially the same manner as the heat absorber shown in FIG. 5, but with an inverted orientation. Heat is transferred out of the heat sink by means of the intermediate fluid (liquid or gas), which is at a relatively low temperature when it enters cross-flow microchannel core 15 via inlet pipe 36 and inlet manifold 37, and which exits cross-flow microchannel core 15 at a higher temperature via outlet manifold 39 and outlet pipe 42. Condensation of vaporized working fluid occurs in a manner substantially the same as described above with respect to FIG. 7, except that heat exits the heat sink via the intermediate fluid.

In another embodiment of the invention, the heat sink is constructed in substantially the same manner as the heat absorber shown in FIG. 6, but with an inverted orientation. Entry and condensation of vaporized working fluid 24, and return of liquid working fluid 28, occur substantially the same way as described with respect to FIG. 8, and heat is transferred out of the heat sink in substantially the same way as in the device of FIG. 1. In another embodiment common connecting pipe 32 has an annular or co-axial wick for co-axial counter-flow of the liquid and vaporized working fluid, as described previously.

In another embodiment of the invention, the heat sink is constructed in substantially the same manner as the heat absorber shown in FIG. 3, but with an inverted orientation. Heat is removed from the heat sink by thermal conduction through the outer surfaces into a cooling medium. The cooling medium may be a fluid (e.g., the heat sink is immersed), or a cool solid which is kept cool by external means, e.g., by refrigeration, thermo-electric cooling, evaporations of an external fluid, sensible heating of a flowing external fluid, etc. Condensation of vaporized working fluid occurs in a manner substantially the same as described above with respect to FIG. 7.

In another embodiment of the invention, the heat sink is constructed in substantially the same manner as the heat absorber shown in FIG. 4, but with an inverted orientation. Entry and condensation of vaporized working fluid 24, and return of liquid working fluid 28, occur substantially the same way as described with respect to FIG. 8, and heat is removed from the heat sink by thermal conduction through the outer surfaces into a cooling medium as described in the immediately preceding embodiment. In another embodiment, common connecting pipe 32 has an annular or co-axial wick for co-axial counter-flow of the liquid and vaporized working fluid, as described previously.

According to the invention, any microchannel heat absorber may be combined with any heat sink. Microchannel heat sinks will be used in many situations. For example, the heat sink of FIG. 8 may be combined with the heat absorber of FIG. 4. Or, the heat sink of FIG. 7 may be combined with the heat absorber of FIG. 3. Other combinations will be apparent to those of skill in the art, and all of these are contemplated by the invention.

### Working Fluids

Many fluids may be used as the working fluid in heat pipes according to the invention. The fluid must have sufficient vapor pressure under the temperature and pressure conditions of use to allow significant vaporization and condensation, as described earlier herein. Since temperature and pressure conditions vary substantially from one application to the next, a wide variety of fluids may be used. Common examples include water, alcohols and hydrocarbons. The inventor has found that heat pipes according to the invention are particularly useful when the working fluid is a fluorocarbon (FC) or hydrofluorocarbon (HFC) or a chlorofluoroalkene (CFA) or a chlorinated hydrofluoroalkene (CHFA), or a mixture of these. In the event of a loss of containment, these materials are unlikely to ignite, have minimal adverse environmental or health consequences, cause no damage to electronic components, create no risk of electric shock, and are readily dissipated. They are low in toxicity, electrically non-conductive, non-corrosive to most materials, and have little or no flammability.

Suitable FC, HFC, CFA or CHFA working fluids will typically be chosen to match their thermodynamic properties to the particular working temperatures and pressures of the heat pipe systems in which they are used. Exemplary fluids include any of the various commercially available pentafluoropropanes, hexafluoropropanes, pentafluorobutanes, and monochloro fluoropropenes. For heat pipes operating in the range of ambient (about 20° C.) to about 100° C., exemplary suitable working fluids include those having normal boiling points (i.e., boiling points at atmospheric pressure) in the range of 10° C. to 80° C., and more typically in a range from 10° C. to 45° C. Suitable classes of HFC's include pentafluoropropanes, hexafluoropropanes, and pentafluorobutanes. Specific examples of suitable HFC's include HFC-245fa, HFC-245ca, HFC-236ca, HFC-365mfc, and mixtures thereof. Specific examples of suitable CHFA's include HCFC 1233zd, and HCFC 1233cf. Heat pipe systems including these working fluids typically operate at pressures mildly elevated with respect to atmospheric pressure. In some embodiments, heat pipes according to the invention may have heat sinks operating at a condensation temperature of about 30° C. to about 50° C., and HFC-245fa, HFC-245ca, HFC-236ca, HFC-365mfc, HCFC 1233zd, and HCFC 1233cf may be particularly well suited for use in such systems.

In one embodiment, the invention provides a method of cooling an article, liquid, or gas with heat pipe system using as its working fluid HFC-245fa, HFC-245ca, HFC-236ca, HFC-365mfc, HCFC 1233zd, HCFC 1233cf, or a mixture of these. In this embodiment the structure of the heat pipe may be any described herein, but the inventor contemplates the use of these fluids in a heat pipe of any structure as well. Thus heat pipe systems of any structure containing these fluids, and methods of cooling by the use of such systems, are also claimed.

The interconnecting pipe(s) need not be integral with the heat absorber or heat sink sections. The connecting pipes may be assembled separately from and joined to the heat absorber and heat sink sections. As a consequence, the interconnecting pipes can be of any convenient length, provided that the pressure drop is less than the driving force (gravity and/or capillary pressure) for returning the condensed liquid to the heat absorber. The use of relatively long interconnecting pipes allows the heat sink and its associated cooling medium to be located remotely from the heat source. In some embodiments, the length of the pipes may be in a range from 5 to 10 inches. In other embodiments, the length may be from 5 to 10 feet or even from 5 to 30 feet. However, the length may be even greater if the connecting diameter is sufficiently large to keep the pressure drop low enough for good flow.

Warm side pipe 26, cool side pipe 30, and common connecting pipe 32 will typically have smaller cross-sections than the heat absorber or heat sink sections, to facilitate the collection and flow of the liquid and vaporized working fluid. The pipes may be of any arbitrary shape and, if suitably thin-walled, may be readily flexed or bent to accommodate off-set placement of the heat sink relative to the heat absorber, and/or routing of the connecting pipes around other objects.

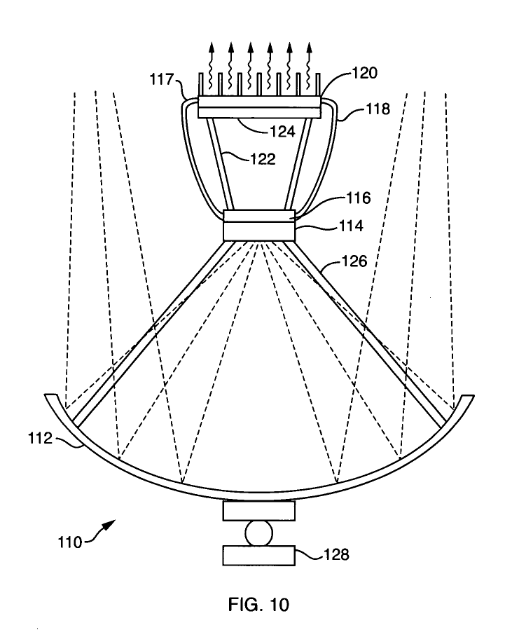

Referring to FIG. 10, an illustrative embodiment of the solar electricity generation system 110 can include a solar concentrating reflector 112 that receives solar radiation and concentrates it onto one or more photovoltaic cells 114. A microchannel heat absorber 116 is coupled to or otherwise positioned proximate the photovoltaic cells so that it can receive heat from them.

A conduit 117 conveys working fluid vapor from the heat absorber 116 to a condenser 120 which may be of a conventional or microchannel design. The condenser can be coupled to or otherwise positioned proximate a thermal electric generator 124 so that it can provide heat to the generator. A return conduit 118 conveys condensed working fluid back to the heat absorber.

Support struts 122 and 126 or other structural members can be used to position the reflector 112, photovoltaic cells 114, heat absorber 116, conduits 117-118, condenser 120, and thermal electric generator 124 with respect to each other. As is well known, a tracking and positioning system 128 can adjust the position of the solar collecting reflector to maximize the amount of received radiation as the Earth rotates.

In operation, the solar concentrating reflector receives solar radiation from the sun and concentrates it on the photovoltaic cells 114. These cells convert energy in the solar radiation directly into electricity. This conversion is not 100% efficient, however, and some of the solar energy heats the cells. This heat vaporizes working fluid in the heat absorber, and the vaporized fluid is then transferred to the condenser 120. Because the orientation of the system takes advantage of the fact that the vaporized fluid tends to rise, the transfer of fluid can take place completely passively. This passive operation can allow the system to be less expensive to implement, more efficient, and more reliable.

The vaporized fluid condenses in the condenser 120 and gives off heat in the process. This heat is collected by the thermal electric generator 124 and converted into additional electricity, which can be used separately or combined with the electricity generated by the photovoltaic cells. Cooling fins or other thermal dissipation elements can be provided on the condenser to help cool it.

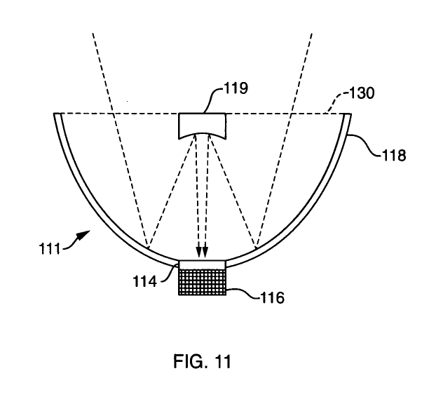

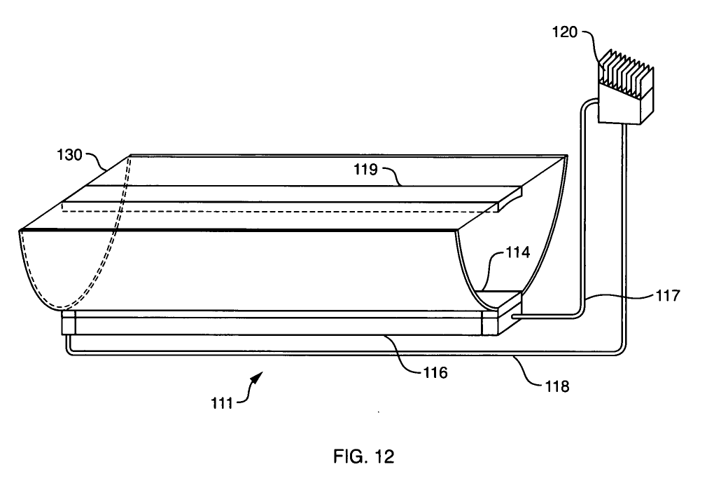

Referring to FIGS. 11-12, a double-reflective-trough-type concentrating solar collection arrangement includes an upright parabolic reflector 118 that concentrates solar radiation on a concave reflector 119. This second reflector reflects the concentrated solar radiation onto a solar cell 114 to which a microchannel heat absorber 116 is thermally connected. Conduits 117-118 convey working fluid from a working fluid outlet manifold on the heat absorber to an air-cooled condenser 120 and then back from the condenser to a working fluid inlet manifold on the heat absorber. By positioning in the condenser above the heat absorber, this arrangement can also be operated passively, although in some circumstances it may be beneficial to actively convey the working fluid, such as with a pump. The use of a separate condenser can also allow multiple cells to drive a single larger condenser that is connected to a larger generator.

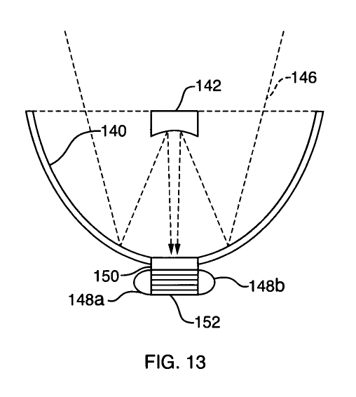

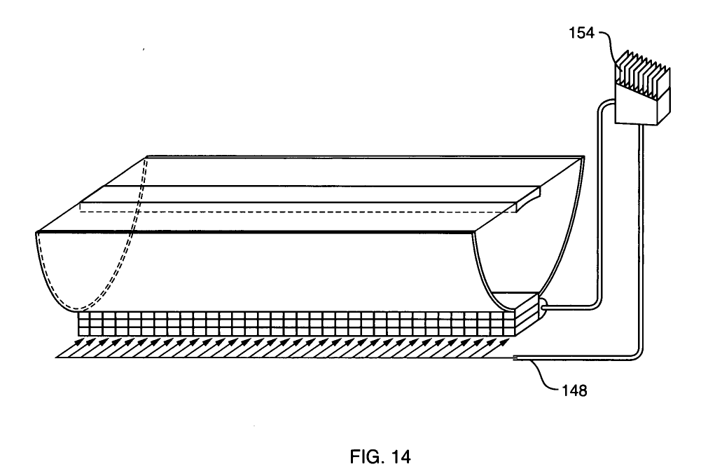

Referring to FIGS. 13-14, a further embodiment employs transverse flow through microchannels oriented perpendicular to the longitudinal dimension of a trough-type concentrating solar collection arrangement. In this embodiment a primary mirror 140 reflects light received through clear glazing 146 on to a secondary mirror 142 that relays it to a solar cell 150. A transverse microchannel heat exchanger 152 is preferably coupled to a bottom surface of the solar cell, with its channels running perpendicular to the longitudinal axis of the collector. An input manifold 148a supplies cooling fluid from a heat sink 152 to the heat exchanger, and an output manifold 148b draws the cooling fluid away from the heat exchanger to a heat sink 156. This arrangement minimizes pressure drop across the heat absorber, allowing the working fluid to boil at a lower temperature to increase the temperature driving force for cooling, providing a higher level of cooling efficiency for a given exchanger size. It also allows the photovoltaic cell to achieve a lower operating temperature and thus increase its electrical conversion efficiency.

Systems according to this aspect of the invention can be advantageous and that can help to recover heat that might otherwise be lost. Recovering this lost heat can improve the overall efficiency of a solar generation facility. And cooling the cells can improve the conversion efficiency of the cells and help to prolong their useful life.

### Examples

### Example 1

### Air-Cooled Single-Tube Non-Wick Heat Pipe System

A heat pipe system is constructed, consisting of a microchannel block-type heat absorber, a finned microchannel heat sink, a connecting pipe, and a working fluid. The heat absorber is an Atotech “Ardex MC-1” microchannel CPU cooler, manufactured by Atotech Deutschland GmbH of Berlin, Germany. One of the two threaded ports is provided with a male adapter ⅜″ tube fitting. The other threaded port is closed off with a pipe plug. The heat sink is an Atotech “Ardex MC-1” microchannel CPU cooler, modified by the addition of thin sheet metal copper cooling fins soldered to the flat side of the MC-1 device. One of the two threaded ports is provided with a male adapter ⅜″ tube fitting. The other threaded port is closed off with a pipe plug. The connecting pipe is a ⅜″ diameter semi-flexible copper or perfluoroalkoxy (PFA) plastic tube, connected to the absorber and heat sink by means of the tube fittings. The connecting pipe is preferably insulated, to minimize heat transfer between the connecting tube and the air space surrounding it. This is useful if the heat pipe connecting tube is within an enclosure (and the heat sink outside the enclosure), to minimize the temperature rise in the enclosure and ensure maximum rejection of heat from the heat source while minimizing heat-up of the enclosure. The connecting pipe is optionally bent, to allow the heat sink to be offset from the heat absorber.

The heat pipe assembly and a container of working fluid (HFC-245fa) is chilled in a domestic refrigerator, to approximately 4.4° C. (40° F.). The chilled liquid working fluid is charged to the heat pipe assembly by removing the pipe plug from the heat absorber, and poured in until the liquid level is approximately at same level as the top of the microchannel plate stack. After charging with the working fluid, the pipe plug is replaced, sealing the system.

The heat pipe assembly is oriented vertically, with the heat absorber block at the bottom, and the finned heat sink section at the top. The heat absorber block is placed in direct contact with the hot object to be cooled, e.g., a central processing unit (CPU) of a computer, which generates heat during operation. The finned heat sink section is exposed to ambient temperature air, which may optionally be circulated around the fins by means of an external fan, to improve the rate of heat removal.

Conduction of heat from the hot object via the heat transfer block causes the working fluid to boil. The vapors travel via the central potion of the connecting pipe, and are cooled and condensed by conduction with the finned heat sink section, and the heat is rejected by convection to the ambient air. The condensed fluid returns by gravity along the walls of the connecting pipe to the heat transfer block, allowing the cycle to repeat. During operation, the temperature of the working fluid rises to a value intermediate between that of the heat source and that of the ambient air external to the heat sink.

At steady state conditions (e.g., assuming heat generation at a constant rate or wattage) the temperature of the working fluid is determined by the heat absorption being in balance with the heat rejection, according to the following relationships:

$${Q}_{absorbed} = {U}_{absorber} \times {A}_{absorber} \times ( {T}_{hot} - {T}_{fluid} )$$

$${Q}_{rejected} = {U}_{sink} \times {A}_{sink} \times ( {T}_{fluid} - {T}_{air} )$$

$${T}_{fluid} = \frac{( {U}_{absorber} \times {A}_{absorber} \times {T}_{hot} ) + ( {U}_{sink} \times {A}_{sink} \times {T}_{air} )}{{U}_{absorber} \times {A}_{absorber} \times {U}_{sink} \times {A}_{sink}}$$

### Where

Q=heat transfer rate
U=heat transfer coefficient
A=heat transfer area
Tₕₒₜ=temperature of heat source

### Example 2

### Air-Cooled Two-Tube Non-Wick Heat Pipe System

A heat pipe system was constructed, consisting of an Atotech Ardex P microchannel block-type heat absorber, a finned microchannel heat sink, two connecting pipes, and a working fluid. The microchannel heat sink consisted of an Atotech Ardex P microchannel block soldered to a CompUSA Pentium 4 Socket 478 CPU cooler fin-fan assembly. The heat pipe assembly consisted of substantially the same equipment and construction as used in Example 1, with the following differences. The second port of the heat absorber was provided with a ¼″ tube fitting male run tee, in lieu of the pipe plug. The second port of the heat sink was provided with a male adapter ¼″ tube fitting, in lieu of the pipe plug. Two connecting pipes were used. The vapor pipe was a ⅜″ diameter PFA tube, and the liquid pipe was a ¼″ PFA tube. The connecting tubes were connected to the absorber by means of the tube fittings on the heat absorber and the heat sink. The working fluid was charged by means of the unused port on the tee connected to heat absorber. After charging, the port was capped with a tube-fitting plug.

The heat pipe assembly was oriented vertically, with the heat absorber block at the bottom, and the finned heat sink section at the top. The heat absorber block was placed in direct contact with the hot object to be cooled. A 2¼ inch square×½ inch thick aluminum block, provided with an electrical cartridge heater embedded in the middle of the block and connected to a Variac™ power source, was used to simulate the central processing unit (CPU) of a computer, which generates heat during operation. The heated block was provided with a thermocouple embedded in the block, adjacent to the cartridge heater. The finned heat sink section was exposed to ambient-temperature air. (Note, although not done in this example, air may optionally be circulated around the fins by means of an external fan, to improve the rate of heat removal.)

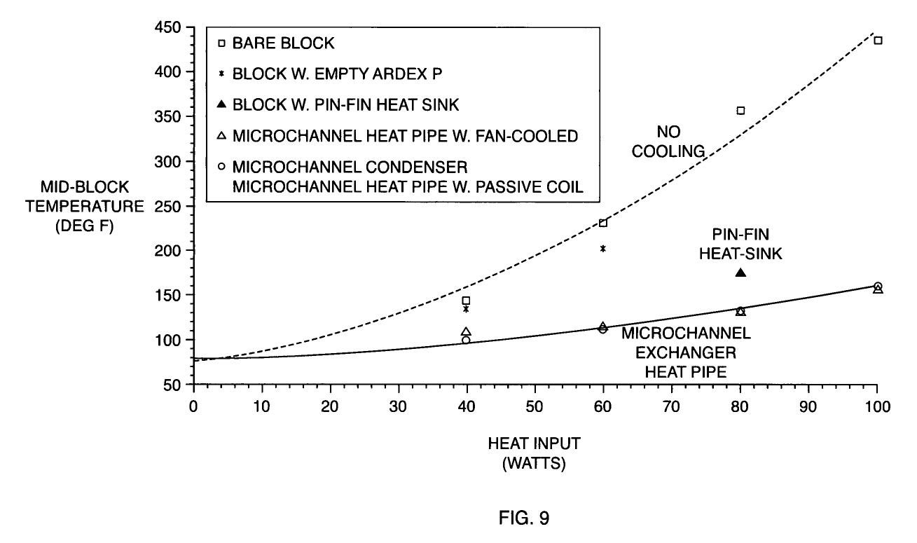

Conduction of heat from the hot object via the heat transfer block caused the working fluid to boil. The vapors traveled via the larger diameter vapor pipe, and are cooled and condensed by conduction with the finned heat sink section, and the heat was rejected by convection to the ambient air. The condensed fluid returned by gravity to the heat transfer block via the smaller diameter liquid return pipe, allowing the cycle to repeat. The fluid flow was visible in the semi-transparent PFA tubing. The temperature and pressure of the working fluid reached steady state, substantially as described in Example 1. A plot of the block temperature as a function of cartridge heater power (wattage) is shown in FIG. 9, in comparison with the temperatures obtained using an un-cooled block, a block cooled by a conventional “pin-fin” CPU cooler, and an empty Ardex P cooling block.

As can be seen from the data in FIG. 9, the bare block without cooling became extremely hot at the higher power input levels, and a prior art pin-fin CPU cooler provided some degree of cooling. However, the two heat pipes using microchannel heat absorbers according to the invention provided substantially more cooling than the pin-fin cooler. In fact, the microchannel systems provided better cooling (lower block temperature) at 100 watts power input than the pin-fin cooler did at only 80 watts. For comparison, a run is also shown using a microchannel heat pipe without any working fluid (labeled “Block w. Empty Ardex P”), and this provided minimal cooling as expected.

### Example 3

### Liquid-Cooled Single-Tube Heat Pipe System

A heat pipe system is constructed, consisting of a microchannel block-type heat absorber, a water-cooled microchannel heat exchanger heat sink, a connecting pipe, and a working fluid. The heat pipe assembly consists of substantially the same equipment as described in Example 2, with the following differences. The heat sink is a cross-flow 2-fluid microchannel heat exchanger. The working fluid is the first fluid, and flowing cooling water is the second fluid, so that heat is removed from the system by heat transfer from the condensing working fluid vapors, through the walls of the microchannel heat sink, into the cooling water.

### Example 4

### Air-Cooled Single-Tube Heat Pipe System with Wick

A heat pipe system similar to that of Example 1 is constructed, except that an annular band of porous wicking material is inserted along the inside wall of the connecting pipe. In this example, the wicking material is an annular roll of sintered −35+65 mesh spherical fine-mesh stainless steel powder. The wicking material causes the condensed working fluid to return to the heat absorber block by capillary action. This allows the heat pipe to be oriented horizontally or even with the heat sink section below the heat absorber block, provided that the capillary force is greater than the gravitational force acting on the returning fluid.

### Example 5

### Air-Cooled Dual-Tube Heat Pipe with Liquid Return Line Wick

A heat pipe system similar to that of Example 2 is constructed, except that the liquid return pipe is packed with porous wicking material. In this example, the wicking material is a braid of fiberglass. The wicking material causes the condensed working fluid to return to the heat absorber block by capillary action. This allows the heat pipe to be oriented horizontally or even with the heat sink section below the heat absorber block, provided that the capillary force is greater than the gravitational force acting on the returning fluid.

### Example 6

### Cooling of a Concentrating Photovoltaic Cell by Means of a Microchannel Heat Pipe, Rejecting the Heat Externally to the Atmosphere

A heat pipe system similar to that of Example 2 is constructed with the heat absorber in contact with the back surface of a photovoltaic (PV) cell located at the focus of a solar concentrator, to provide a means of cooling to remove the heat generated by the portion of the light spectrum that is absorbed by the PV cell but is not converted to electricity. The connecting tubes for the working fluid are routed to an elevated portion away from the solar concentrator assembly, and the finned heat sink is exposed to the ambient air. The heat sink and connecting tubes are preferably located in such a way that they do not cast a shadow on the solar concentrator assembly. Using this configuration, the heat removed from the PV cell is passively rejected to the atmosphere, where natural convection carries it away form the solar concentrator assembly.

The microchannel heat absorber is preferably constructed such that the microchannels are aligned along the short axis of the PV cells, to minimize the channel length and thus the pressure drop across the microchannels, to maximize the flow rate of the working fluid, thereby minimizing the boiling pressure and thus temperature of the working fluid. This maximizes the cooling rate, minimizing the operating temperature and thus maximizing the electrical conversion efficiency of the PV cell.

### Example 7

### Cooling of a Single-Reflective Concentrating Photovoltaic Cell by Means of a Microchannel Heat Pipe

The concentrating PV cell of Example 6 can be used with a single-reflective design, wherein a reflective parabolic dish or trough is located beneath and focuses the light on an (externally supported) downward-facing PV cell provided with a microchannel heat absorber on its back (upward-facing) side. The connecting tubes for the working fluid and the heat sink are supported and located above the PV cell. This is illustrated in FIG. 10.

### Example 8

### Cooling of a Double-Reflective Concentrating Photovoltaic Cell by Means of a Microchannel Heat Pipe

The concentrating PV cell of Example 6 can also be used with a double-reflective design, wherein a reflective parabolic dish or trough covered with a flat sheet or glazing of transparent material, focuses the light on a small secondary mirror affixed to the glazing. The secondary mirror directs the concentrated light onto an upward-facing PV cell provided with a microchannel heat absorber on its back (upward-facing) side, with the PV cell located at or beneath a cut-out in the primary parabolic reflector. This is illustrated in FIG. 11. The connecting tubes for the working fluid and the heat sink are routed to the sides or ends of the concentrator assembly, and the heat sink is elevated with respect to the PV cell and heat absorber. For non-circular or trough-type concentrator systems, the microchannel heat absorber is provided with vapor collection and liquid distribution plenums aligned along the long axis of the heat absorber, with the microchannels aligned perpendicular to the long axis, allowing the working fluid connecting tubes to be located at the long ends of the concentrator assembly, as illustrated in FIG. 12. This allows multiple concentrator assemblies to be placed immediately adjacent to each other, maximizing the fraction of active light-collection area covering a given surface.

### Example 9

### Cooling of a Fresnel-Lens Concentrating Photovoltaic Cell by Means of a Microchannel Heat Pipe

The concentrating PV cell of Example 6 can also be used with a Fresnel-lens concentrator design wherein upward-facing segments of active photovoltaic material are covered with a series of transparent focusing ridges, e.g. Fresnel lenses or similar devices, which concentrate the light onto the PV cells. A microchannel heat absorber is affixed to the back side of the substantially flat PV cell/Fresnel lens assembly. The connecting tubes for the working fluid and the heat sink are routed to the sides or ends of the flat concentrator assembly, and the heat sink is elevated with respect to the PV cell and heat absorber. For non-circular rectangular concentrator systems, the microchannel heat absorber is provided with vapor collection and liquid distribution plenums aligned along the long axis of the heat absorber, with the microchannels aligned perpendicular to the long axis, allowing the working fluid connecting tubes to be located at the long ends of the concentrator assembly.

### Example 10

### Cooling of a Concentrating Photovoltaic Cell by Means of a Microchannel Heat Pipe Used as the Substrate for the Photovoltaic Cell

The arrangement of Example 6 can also be used with a microchannel heat absorber being the substrate for the photovoltaic cell, i.e. the active PV components are deposited directly onto the surface of the microchannel heat absorber. This offers the advantages of minimizing the conductive heat transfer resistance between the active PV components and the boiling working fluid (no need for additional substrates or bonding between the PV cell and the heat absorber), and simplifies the manufacture of the completed cooled solar concentrator assemblies.

### Example 11

### Cooling of Multiple Concentrating Photovoltaic Cells by Means of Microchannel Heat Pipes, Rejecting the Heat Externally to the Atmosphere via a Common Heat Sink

The arrangement of Example 6 may be repeated for multiple concentrating PV cells or arrays, with some or all of the heat pipes manifolded to common vapor collection and liquid return headers, which are in turn connected to a common large heat sink exposed to the ambient air, said heat sink having adequate cooling capacity to reject the collective heat from all of the connected PV cells.

### Example 12

### Increase in the Maximum or Optimum Concentration Factor and Power Generation for Concentrating Photovoltaic Cells Cooled by Means of Microchannel Heat Pipes, Compared to Conventional Cooling Means

The relationship for heat transfer between a photovoltaic (PV) cell and a fluid cooling medium is described by the relation:

Q=U*A*(T−T_{coolant})

where T is the PV cell temperature, and U is overall heat transfer coefficient. Note that for U for a system consisting of a thermally conductive wall and a moving fluid can be calculated from the relation:

1/U=1/h_{fluid}+l_{wall}/k_{wall}

where h_{fluid} is the individual (wall-side) fluid heat transfer coefficient, l_{wall} is the wall thickness of the heat transfer surface, and k_{wall} is the thermal conductivity of the heat transfer surface.

The heat transfer relation above can be re-arranged to give the formula for the heat flux, Q/A (heat transfer per unit area), given in Equation (1):

(Q/A)=U*(T−T_{coolant}) (1)

The incident solar power per unit area, Pᵢ, of sunlight directed onto the surface of a photovoltaic (PV) cell is described by Equation (2):

Pᵢ=S*X (2)

where S is the solar insolation (light intensity per unit area), and X is concentrator multiplier.

The total power per unit area Pₜ transmitted to the PV cell surface (after reflection) is described by Equation (3):

$$\begin{matrix}{P}_{t} = {P}_{i} * ( 1 - α ) \\ = S * X * ( 1 - α )\end{matrix} \qquad ( 3 )$$

where α is the fraction of incident power reflected off cell surface.

It is well known that electrical conversion efficiency, η, of PV cells decreases with increasing operating temperature. For most PV cell materials, the efficiency decreases substantially linearly with, and may be described by the relation of Equation (4):

η=m*T+b (4)

where m is the efficiency loss per unit temperature, i.e. (negative) slope of the conversion vs. temperature graph for a given PV material, and b is the efficiency at zero degrees Celsius, i.e. intercept of the conversion-temperature graph.

The net power converted to electricity per unit area, P_{c}, is the total power transmitted to the PV cell surface times the efficiency, i.e.

P_{c}=η*Pₜ

Combing this with the Equations 3 and 4, gives the power conversion to electricity per unit area as a function of the temperature-efficiency relationship, insolation, concentration factor, and PV cell reflectance, as shown in Equation (5)

P_{c}=(m*T+b)*S*X*(1−α) (5)

The solar power per unit area lost to heating, Pₕ, is the total power transmitted to the PV cell surface less the power converted to electricity, which is described by Equation (6):

$$\begin{matrix}{P}_{h} = {P}_{t} - {P}_{c} \\ = S * X * ( 1 - α ) * [ 1 - ( m * T + b ) ]\end{matrix} \qquad ( 6 )$$

However, at steady state, solar power per unit lost to heating is equal to heat flux removed by cooling [from Equation (1)], as shown in equation (7):

Pₕ=Q/A (7)

Substituting Equations (1) and (6), and rearranging terms, the PV cell temperature can be calculated from the solar electric conversion parameters, overall heat transfer coefficient, and coolant fluid temperature, and light concentration factor as shown in equation (8):

T=[S*X*(1−α)*(1−b)+U*T_{coolant}]/[U+S*X*(1−α)*m] (8)

Thus for a given coolant temperature and overall heat transfer coefficient, one can calculate and plot the PV cell temperature vs. solar concentration factor. Once the PV cell temperature is known, it can be substituted back into Equation (5) to solve for and plot the electric power generation per unit cell area vs. the solar concentration multiplier. As will be shown below, the latter increases to a maximum value with increasing concentration, and then decreases at higher concentration factors, because the efficiency lost due to heating outweighs the power gain due to further concentration. The optimum concentration factor corresponds to the maximum electrical power output. As the costs per unit area of the active PV material is typically much higher than that of the concentrator system, the optimum concentration factor represents the economically optimum design for a concentrating PV system.

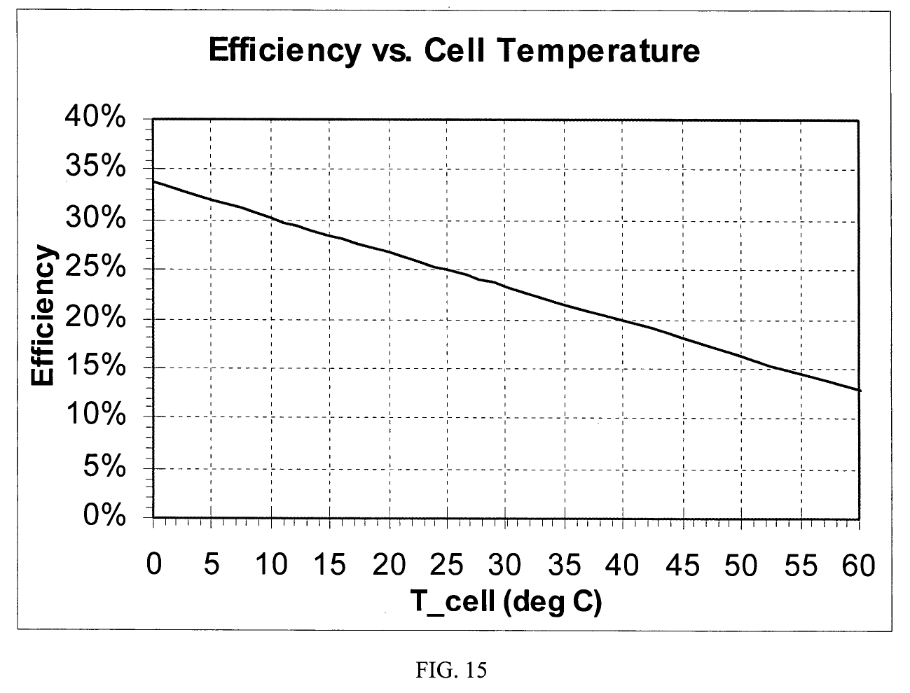

In the following examples, the efficiencies for a solar cell are assumed to be 25% at 25° C. and 9.3% at 70° C. A linear temperature/efficiency relationship is assumed, as shown in FIG. 15; from which m=−0.349% per deg C, and b=33.72% efficiency at 0° C.

It is further assumed that the heat is ultimately rejected to air at 35° C., typical for a summer afternoon temperature in the Southwestern United States. A typical solar insolation value (S) for this region is 340 W/m² m (see, for example, http://www.answers.com/topic/insolation). A typical solar cell reflectance of 13.8% (i.e. α=0.138) is assumed.

Example 12a assumes that the PV cell is conventionally air-cooled by natural convection using a finned aluminum block, 1 mm thick with multiple fins. The thermal conductivity of aluminum is 237 W/m-K, and a typical convective heat transfer coefficient (h_{fluid}) of 55 W/m²-K (=9.7 BTU/hr-ft²-° F.) is assumed. Assuming that the cooling fins increases the “effective” overall heat transfer by a factor of 8, this gives an effective U value of 439.7 W/m²-K. Since the heat is being rejected directly to the air by the fins, T_{coolant} is the air temperature, i.e. 35° C.

Example 12b assumes that the PV cell is conventionally air-cooled by forced convection using a fan blowing air across the aluminum block of Example 7, with a typical convective heat transfer coefficient (h_{fluid}) of 170 W/m²-K (=30 BTU/hr-ft²-° F.) is assumed. Assuming that the cooling fins increases the “effective” overall heat transfer by a factor of 8, this gives an effective U value of 1369 W/m²-K. Since the heat is being rejected directly to the air by the fins, T_{coolant} is the air temperature, i.e. 35° C.

Example 12c assumes that the PV cell is conventionally liquid-cooled by forced convection using water circulating through a copper block, 1 mm thick. The thermal conductivity of copper is 400 W/m-K. A typical water-side convective heat transfer coefficient (Num) of 4500 W/m²-K (=792 BTU/hr-ft²-° F.) is assumed. This gives an overall U value of 4401 W/m²-K. It is assume that the cooling water circulates in a closed loop, rejects the heat to an air cooler, with a temperature approach within 6° C. of the ambient air. Thus T_{coolant} is 41° C.

Example 12d assumes that the PV cell is cooled by a boiling working fluid in a microchannel heat pipe (MHP). The MHP consists of a copper microchannel heat exchanger with a 0.5 mm surface thickness bonded to the PV cell, 6 layers of microchannels effectively multiplying the cooling area by a factor of 6, and the heat rejected to ambient air via an air-fin cooler, allowing the working fluid to condense and return to the heat absorber. The thermal conductivity of copper is 400 W/m-K. A working fluid-side convective heat transfer coefficient (h_{fluid}) in the microchannels of 15,000 W/m²-K (=2642 BTU/hr-ft²-° F.) is assumed, based on published figures (see http://www.ebecem.com.br/download/02.pdf). This gives an effective overall U value of 88,340 W/m²-K. It is assumed that the working fluid rejects the heat by condensation, achieves a temperature approach within 4° C. of the ambient air. Thus T_{coolant} is 39° C.

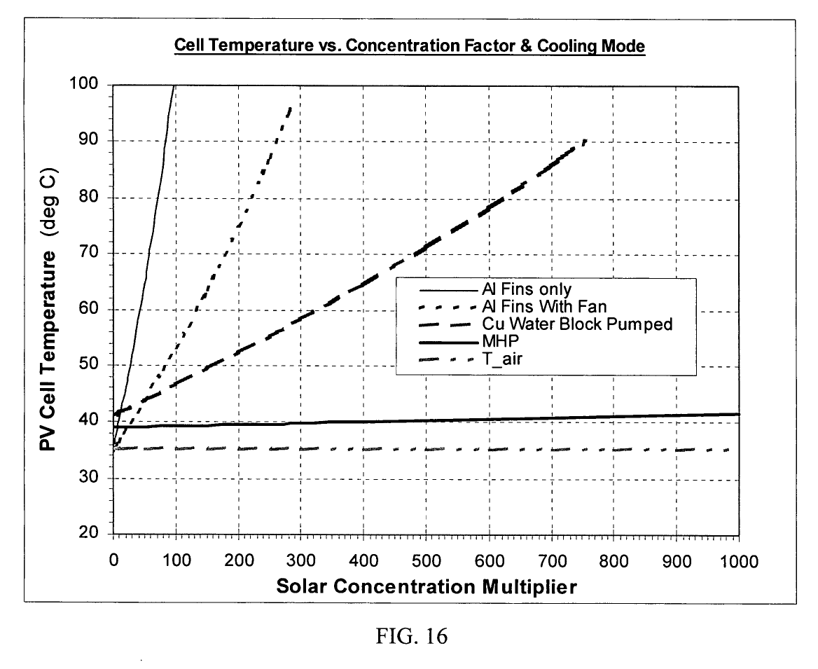

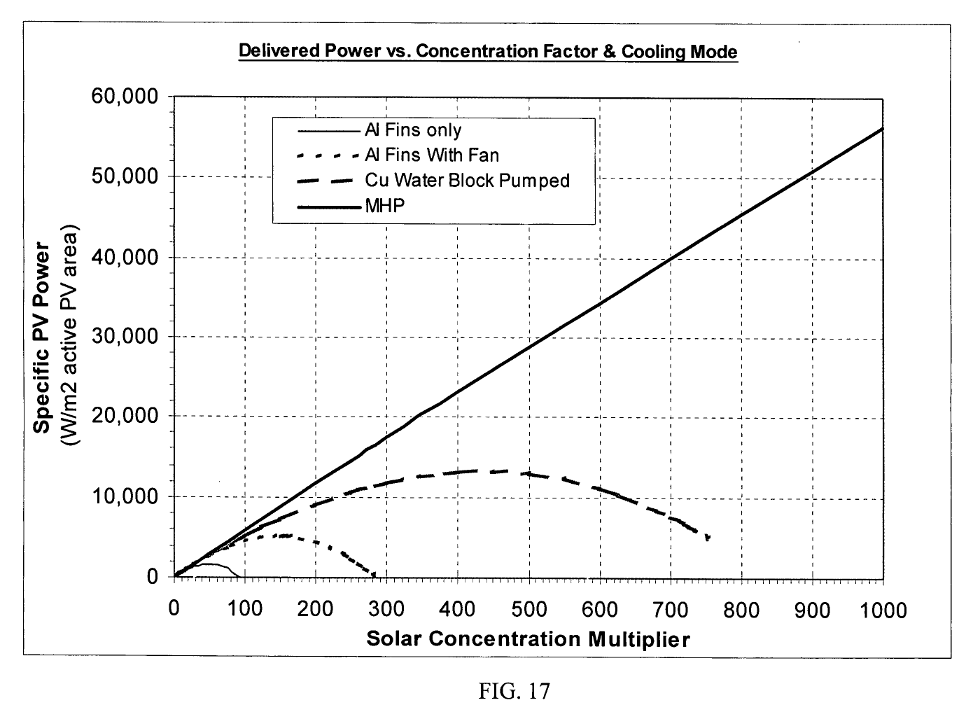

The PV cell temperatures for Examples 6, 7, 8, 9, and 10 are calculated using Equation (8) for a range of solar concentration factors. The PV cell specific power outputs are calculated from these temperatures, using Equation (5). The results are shown in FIGS. 16 and 17.

These figures show that the microchannel heat pipe, with its extremely high effective heat transfer, is able to maintain the PV cell temperature within a few degrees of the ambient air temperature, thus maintaining high electrical conversion efficiencies, with solar concentration factors as great as 1000. In contrast, the conventional cooling approaches result in the PV cell temperatures to exceed 70° C., with a corresponding 2½ fold reduction in electrical conversion efficiency, at much lower concentration factors.

Under the assumptions given above, the optimum concentration factors are about 50 for the air-fin with natural convection, about 160 for the fin-fan cooler, and about 450 for the pumped water-cooled block. In contrast, with the microchannel heat pipe, the optimum (maximum power output) was not reached even at a concentration factor as high as 1000, which is approaching the current practical limits for solar concentrators. The corresponding maximum specific power outputs for the concentrating photovoltaic systems are about 1.7 kW/m² for the air-fin with natural convection, about 5.1 kW/m² for the fin-fan cooler, and about 13.1 kW/m² for the pumped water-cooled block. In contrast, with the microchannel heat pipe, could in principle deliver greater than 56 kW W/m², and is limited by the attainable concentration factor, rather than by cooling.

This example clearly demonstrates how microchannel heat pipe cooling systems can enable orders-of-magnitude higher power output for concentrating photovoltaic systems, with a corresponding reduction in the fixed costs per installed watt of power capacity.

Although the invention is illustrated and described herein with reference to specific embodiments, it is not intended that the subjoined claims be limited to the details shown. Rather, it is expected that various modifications may be made in these details by those skilled in the art, which modifications may still be within the spirit and scope of the claimed subject matter and it is intended that these claims be construed accordingly.

What is claimed is:

1. A solar electricity generation system, comprising:
a solar concentrator positioned to receive and concentrate solar radiation,
a photovoltaic solar cell positioned to receive the concentrated solar radiation from the solar concentrator and operative to convert part of the energy in the concentrated solar radiation into electricity and part of the energy in the concentrated solar radiation into heat,
a first heat exchanger comprising a plurality of microchannels having a cross-sectional dimension to the center of the channel that is about equal to or less than the thermal boundary layer thickness for a working fluid, being thermally coupled to the solar cell, and being operative to transfer the heat from the photovoltaic solar cell to the working fluid in the microchannels,
a conduit having a first end hydraulically responsive to the heat exchanger and having a second end, and
a second heat exchanger hydraulically responsive to the second end of the conduit.

2. The solar electricity generation system of claim 1, further comprising an electric generator thermally coupled to the second heat exchanger and operative to produce electricity from heat transferred from the first heat exchanger to the second heat exchanger by the working fluid.

3. The solar electricity generation system of claim 1, wherein the second heat exchanger also comprises microchannels having a cross-sectional dimension to the center of the channel that is about equal to or less than the thermal boundary layer thickness for the working fluid.

4. The solar electricity generation system of claim 1, wherein the heat exchangers and the conduit are constructed and adapted to operate with a working fluid that changes phases during operation of the system.

5. The solar electricity generation system of claim 1, further comprising further photovoltaic solar cells responsive to concentrated solar radiation, further comprising further first heat exchangers thermally coupled to the further photovoltaic cells, and further comprising further conduits hydraulically connected between the further first heat exchangers and the second heat exchanger.

6-19. (canceled)

20. A solar electricity generation method, comprising:
concentrating solar radiation,
converting part of the energy in the concentrated solar radiation into electricity and part of the energy in the concentrated solar radiation into heat,
transferring at least some of the heat from the photovoltaic solar cell to a working fluid in a plurality of microchannels having a cross-sectional dimension to the center of the channel that is about equal to or less than the thermal boundary layer thickness for the working fluid,
causing the working fluid to flow to another location, and
extracting at least some of the heat from the working fluid after causing it to flow to another location.

21-31. (canceled)

32. A solar electricity generation system, comprising:
means for concentrating solar radiation,
means for converting part of the energy in the concentrated solar radiation into electricity and part of the energy in the concentrated solar radiation into heat,
means for transferring at least some of the heat from the photovoltaic solar cell to a working fluid in a plurality of microchannels having a cross-sectional dimension to the center of the channel that is about equal to or less than the thermal boundary layer thickness for the working fluid,
means for causing the working fluid to flow to another location, and
means for extracting at least some of the heat from the working fluid after causing it to flow to another location.

33. (canceled)
